(19) United States
(12) Patent Application Publication
(10) Pub. No.: US 2026/0247834 A1
(43) Pub. Date: Aug. 20, 2026

(54) Electronic Device And Method For Manufacturing Electronic Device

(71) Applicant: Samsung Display Co., Ltd., Yongin-si (KR)

(72) Inventors: Ju-Hyun Shin, Yongin-si (KR); Dongsoup Noh, Yongin-si (KR)

(73) Assignee: Samsung Display Co., Ltd., Yongin-si (KR)

(21) Appl. No.: 19/378,917

(22) Filed: Nov. 4, 2025

(30) Foreign Application Priority Data
Feb. 17, 2025 (KR) 10-2025-0020042

(51) Int. Cl. H10K 59/80; H05K 1/18; H10K 59/12; H10K 59/131; H10K 59/40; H10K 71/70; H10K 102/00

(52) U.S. Cl. CPC H10K 59/8722; H05K 1/189; H10K 59/1201; H10K 59/131; H10K 59/40; H10K 71/70; H05K 2201/10128; H10K 2102/351

(57) ABSTRACT

Provided is an electronic device including a display panel having a display region, and a non-display region adjacent to the display region and comprising a display pad region where a display pad is disposed and a test pad region where a test pad is disposed, a flexible circuit board disposed on the display panel and having a circuit pad disposed corresponding to the display pad, a conductive tape disposed on the flexible circuit board, and an adhesive layer disposed between the display panel and the conductive tape. The adhesive layer overlaps the display pad region and the test pad region, a thickness of the adhesive layer overlapping the display pad region is defined as a first thickness, a thickness of the adhesive layer overlapping the test pad region is defined as a second thickness, and the first thickness is smaller than the second thickness.

### CROSS-REFERENCE TO RELATED APPLICATIONS

This U.S. non-provisional patent application claims priority under 35 U.S.C. § 119 of Korean Patent Application No. 10-2025-0020042, filed on Feb. 17, 2025, the entire contents of which are hereby incorporated by reference.

### BACKGROUND

The present disclosure herein relates to an electronic device and a method for manufacturing an electronic device, and more particularly, to an electronic device including a display pad and a test pad and a method for manufacturing the same.

Multimedia electronic devices such as televisions, mobile phones, tablet PCs, navigation systems, and game consoles may include a display module for displaying an image and sensing an external input.

The display module may be bonded and electrically connected to an electronic component such as a flexible circuit board.

### SUMMARY

The present disclosure provides an electronic device with improved reliability by sealing a test pad to prevent corrosion of the test pad due to moisture penetration, and by insulating between the test pad and a conductive tape to prevent a defect due to a short-circuit.

The present disclosure also provides a method for manufacturing an electronic device with improved reliability, without adding a separate process step.

An embodiment of the inventive concept provides an electronic device including: a display panel having a display region where a light-emitting element is disposed, and a non-display region adjacent to the display region and comprising a display pad region where a display pad is disposed and a test pad region where a test pad is disposed; a flexible circuit board disposed on the display panel, and having a circuit pad disposed corresponding to the display pad on a plane; a conductive tape disposed on the flexible circuit board; and an adhesive layer disposed between the display panel and the conductive tape, wherein on a plane, the adhesive layer overlaps the display pad region and the test pad region, a thickness of the adhesive layer overlapping the display pad region is defined as a first thickness, a thickness of the adhesive layer overlapping the test pad region is defined as a second thickness, and the first thickness is smaller than the second thickness.

In an embodiment, on a plane, the flexible circuit board may overlap the display pad region, and may not overlap the test pad region.

In an embodiment, the flexible circuit board may be disposed between the adhesive layer and the conductive tape.

In an embodiment, the adhesive layer may include an adhesive resin which contains an insulating material, and is in contact with the display panel, the flexible circuit board, and the conductive tape, and a conductive particle disposed within the adhesive resin, and the conductive particle may be in contact with each of the display pad and the circuit pad to electrically connect the display panel and the flexible circuit board.

In an embodiment, the adhesive resin may cover the test pad.

In an embodiment, the conductive particle included in the adhesive layer overlapping the test pad region may be spaced apart from the test pad with the adhesive resin between the conductive particle and the test pad, and the conductive particle included in the adhesive layer overlapping the test pad region may be spaced apart from the conductive tape with the adhesive resin between the conductive particle and the conductive tape.

In an embodiment, on a plane, the conductive tape may overlap the display pad region and the test pad region.

An embodiment of the inventive concept provides an electronic device including: a display panel having a display region where a light-emitting element is disposed, and a non-display region adjacent to the display region and comprising a display pad region where a display pad is disposed and a test pad region where a test pad is disposed; a flexible circuit board disposed on the display panel, and having a circuit pad disposed corresponding to the display pad on a plane; a conductive tape disposed on the flexible circuit board; and an adhesive layer disposed between the display panel and the conductive tape, and overlapping the display pad region and the test pad region, on a plane, wherein the adhesive layer includes an adhesive resin which contains an insulating material and is in contact with the display panel, the flexible circuit board, and the conductive tape, and a conductive particle disposed within the adhesive resin, the conductive particle included in the adhesive layer overlapping the test pad region is spaced apart from the test pad with the adhesive resin between the conductive particle and the test pad, and the conductive particle included in the adhesive layer overlapping the test pad region is spaced apart from the conductive tape with the adhesive resin between the conductive particle and the conductive tape.

In an embodiment, the conductive particle may be in contact with each of the display pad and the circuit pad to electrically connect the display panel and the flexible circuit board.

In an embodiment, a thickness of the adhesive layer overlapping the display pad region may be defined as a first thickness, a thickness of the adhesive layer overlapping the test pad region may be defined as a second thickness, and the first thickness may be smaller than the second thickness.

In an embodiment, on a plane, the flexible circuit board may overlap the display pad region, and may not overlap the test pad region, and the flexible circuit board may be disposed between the adhesive layer and the conductive tape.

In an embodiment, the adhesive resin may cover the test pad.

In an embodiment, on a plane, the conductive tape may overlap the display pad region and the test pad region.

In an embodiment, the electronic device may further include at least one of a processor, a memory, or a power module.

In an embodiment, the electronic device may be a television, a monitor, an outdoor billboard, a personal computer, a laptop computer, a personal digital terminal, a car's instrument cluster, a center fascia, a navigation system, a room mirror display, a game console, a smart phone, a tablet PC, a smart watch, smart glasses, a head mounted display, or a camera.

An embodiment of the inventive concept provides a method for manufacturing an electronic device including: disposing an adhesive film between a display panel, which has a display pad region where a display pad is disposed and a test pad region where a test pad is disposed, and a flexible circuit board, which has a circuit pad, and compressing the flexible circuit board toward the display panel; forming an adhesive layer by curing the adhesive film compressed by the flexible circuit board and the display panel; and disposing, on the flexible circuit board and the adhesive layer, a conductive tape to overlap the display pad region and the test pad region, wherein in the compressing, the adhesive film is disposed to overlap the display pad region and the test pad region, and the flexible circuit board is disposed to overlap the display pad region and not to overlap the test pad region, a thickness of the adhesive layer overlapping the display pad region is formed as a first thickness, and a thickness of the adhesive layer overlapping the test pad region is formed as a second thickness which is greater than the first thickness.

In an embodiment, in the compressing, the flexible circuit board may be disposed such that the circuit pad corresponds to the display pad.

In an embodiment, the adhesive layer may include an adhesive resin which contains an insulating material, and is in contact with the display panel, the flexible circuit board, and the conductive tape, and a conductive particle disposed within the adhesive resin, and the conductive particle may be in contact with each of the display pad and the circuit pad to electrically connect the display panel and the flexible circuit board.

In an embodiment, the conductive particle included in the adhesive layer overlapping the test pad region may be spaced apart from the test pad with the adhesive resin between the conductive particle and the test pad, and the conductive particle included in the adhesive layer overlapping the test pad region may be spaced apart from the conductive tape with the adhesive resin between the conductive particle and the conductive tape.

In an embodiment, the adhesive resin may cover the test pad.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a block diagram of an electronic device according to an embodiment of the inventive concept;

FIG. 2 shows schematic diagrams of various electronic devices according to an embodiment of the inventive concept;

FIG. 3 is an assembled perspective view of an electronic device according to an embodiment of the inventive concept;

FIG. 4 is an exploded perspective view of an electronic device according to an embodiment of the inventive concept;

FIG. 5 is a cross-sectional view of a display module according to an embodiment of the inventive concept;

FIG. 6 is a plan view of a display panel according to an embodiment of the inventive concept;

FIG. 7 is a plan view of an input sensing unit according to an embodiment of the inventive concept;

FIG. 8 is a cross-sectional view of a display module according to an embodiment of the inventive concept;

FIG. 9 is an exploded perspective view of an electronic device according to an embodiment of the inventive concept;

FIG. 10 is a cross-sectional view of an electronic device according to an embodiment of the inventive concept;

FIGS. 11A to 11C are each a schematic diagram illustrating one step of a method for manufacturing an electronic device according to an embodiment of the inventive concept; and

FIG. 12 is a photograph of a cross section of an electronic device according to an embodiment of the inventive concept.

### DETAILED DESCRIPTION

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

Like reference numerals or symbols refer to like elements throughout. Also, in the drawings, the thickness, ratio, and size of the elements are exaggerated for effectively describing the technical contents. As used herein, the term “and/or” includes any and all combinations of one or more of the associated listed elements.

It will be understood that, although the terms “first”, “second”, etc. may be used herein to describe various elements, the elements are not to be limited by these terms. These terms are only used to distinguish one element, component, region, layer or section from another element, component, region, layer or section. For instance, a first element, component, region, layer or section discussed below could be termed a second element, component, region, layer or section without departing from the scope of the inventive concept. Similarly, a second element, component, region, layer or section could be termed a first element, component, region, layer or section. In this specification, the singular expressions “a”, “an” and “the” are intended to include the plural forms as well, unless the context clearly indicates otherwise.

In addition, the terms “below”, “under”, “on the lower side”, “above”, “over”, “on the upper side”, or the like may be used to describe the relationships between the elements illustrated in the drawings. These terms have relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components, or combinations thereof, but do not preclude the possibility of the presence or addition of one or more other features, numbers, steps, operations, elements, components, and/or combinations thereof.

Unless otherwise defined, all terms (including technical and scientific terms) used herein have the same meaning as commonly understood by one of ordinary skills in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept are described with reference to the drawings.

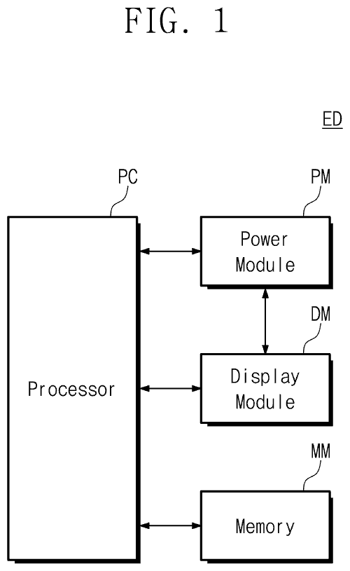

FIG. 1 is a block diagram of an electronic device according to an embodiment of the inventive concept.

Referring to FIG. 1, an electronic device ED according to an embodiment of the inventive concept may include a display module DM, a processor PC, a memory MM, and a power module PM.

The processor PC may include at least one of a central processing unit (CPU), an application processor (AP), a graphic processing unit (GPU), a communication processor (CP), an image signal processor (ISP), or a controller.

In the memory MM, data information necessary for an operation of the processor PC or the display module DM may be stored. When the processor PC executes an application stored in the memory MM, an image data signal and/or an input control signal may be transmitted to the display module DM, and the display module DM may process the received signal and output image information through a display screen.

The power module PM may include a power supply module such as a power adapter or battery unit, and a power conversion module which converts the power provided by the power supply module and generates power necessary for an operation of the electronic device ED.

At least one of the respective components of the electronic device ED described above may be included in a display device according to embodiments to be described later. In addition, some of individual modules functionally included in one module may be included in the display device, and others may be provided separately from the display device. For example, the display device may include the display module DM, and the processor PC, the memory MM, and the power module PM may be provided as a form of another unit within the electronic device ED other than the display device.

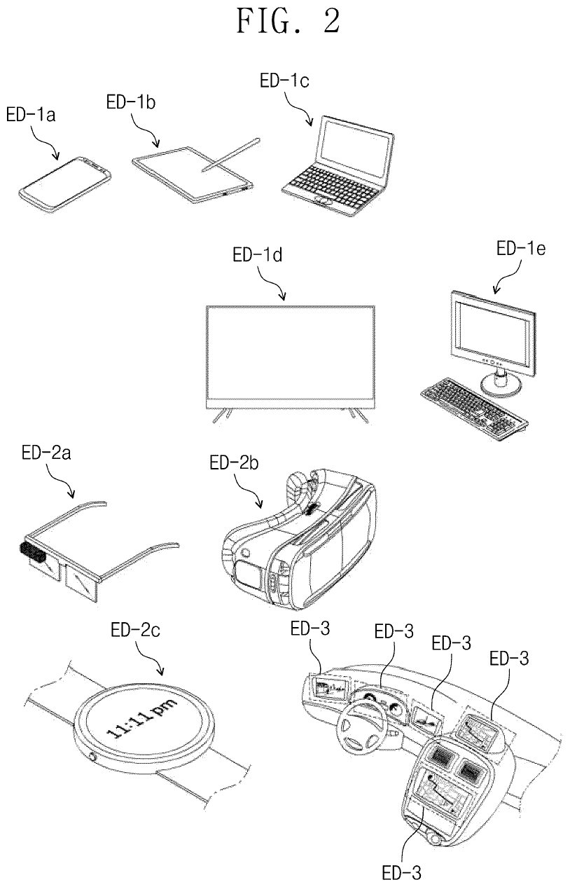

FIG. 2 shows schematic diagrams of various electronic devices according to an embodiment of the inventive concept.

Referring to FIG. 2, various electronic devices to which a display module according to an embodiment of the inventive concept is applied may include not only an electronic device for displaying an image such as a smart phone ED-1a, a tablet PC ED-1b, a laptop computer ED-1c, a TV ED-1d, and a monitor ED-1e for a desk, but also a wearable electronic device such as smart glasses ED-2a, a head-mounted display ED-2b, and a smart watch ED-2c, and an electronic device ED-3 for vehicles such as a room mirror display and a center information display (CID), which is disposed on a car's instrument cluster, center fascia, and dashboard.

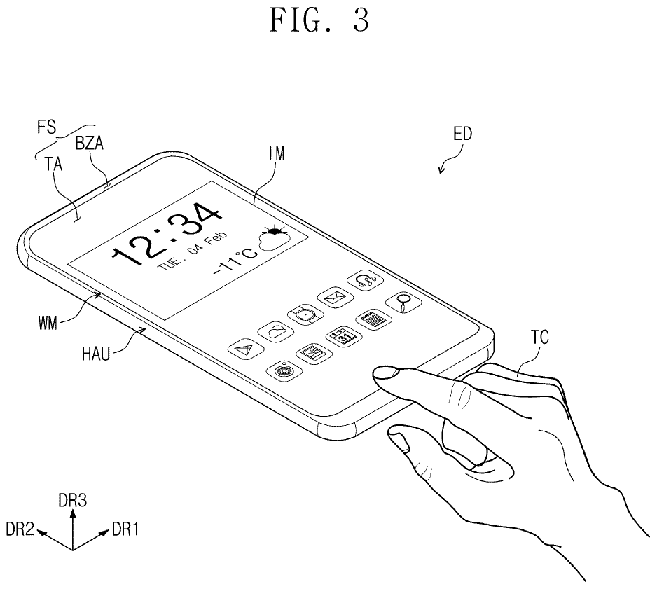

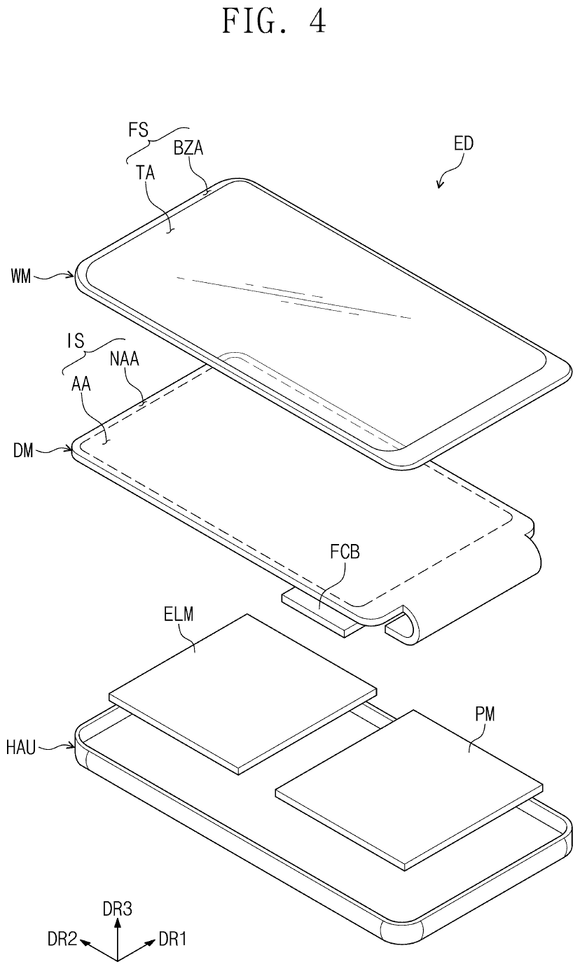

FIG. 3 is an assembled perspective view of an electronic device according to an embodiment of the inventive concept. FIG. 4 is an exploded perspective view of an electronic device according to an embodiment of the inventive concept.

Referring to FIGS. 3 and 4, an electronic device ED may be a device which is activated in response to an electrical signal, displays an image IM, and senses an external input TC. For example, the electronic device ED may include a device such as a television, a monitor, an outdoor billboard, a personal computer, a laptop computer, a personal digital terminal, a car's instrument cluster, a center fascia, a navigation system, a room mirror display, a game console, a smart phone, a tablet PC, a smart watch, smart glasses, a head mounted display, and a camera. However, embodiments of the aforementioned electronic device ED are examples, and are not limited to any one embodiment unless deviating from the idea of the inventive concept. In this embodiment, the electronic device ED is exemplarily illustrated as a mobile phone.

The electronic device ED may have, on a plane, a rectangular shape which has short sides extending in a first direction DR1, and long sides extending in a second direction DR2 crossing the first direction DR1. However, an embodiment of the inventive concept is not limited thereto, and on a plane, the electronic device ED may have various shapes such as a circular shape and a polygonal shape.

In this embodiment, a third direction DR3 may be defined as a direction perpendicular to a plane defined by the first direction DR1 and the second direction DR2. A front surface (or top surface) and a rear surface (or bottom surface) of each member that constitutes the electronic device ED may be opposed to each other in the third direction DR3, and a normal direction of each of the front surface and the rear surface may be substantially parallel to the third direction DR3. A spaced distance, between the front surface and the rear surface, which is defined along the third direction DR3 may correspond to a thickness of the member.

In this specification, the wording “on a plane” may be defined as a “state viewed in the third direction DR3”. In this specification, the wording “on a cross section” may be defined as a “state viewed in the first direction DR1 or the second direction DR2”. The directions indicated by the first to third directions DR1, DR2, and DR3 may have a relative concept and may thus be changed to other directions.

The electronic device ED may be rigid or flexible. The term “flexible” may indicate a bendable property, and may include all structures spanning from a structure which is completely foldable to a structure which is bendable to the level of several nanometers. For example, the flexible electronic device ED may include a curved electronic device, a rollable electronic device, or a foldable electronic device.

The electronic device ED may display the image IM through a display surface FS that is parallel to each of the first direction DR1 and the second direction DR2. The image IM may include a static image as well as a dynamic image. In FIG. 3, a clock and icons are illustrated as an example of the image IM.

The display surface FS of the electronic device ED may only include a flat surface or may further include a curved surface bent from at least one side of the flat surface. The display surface FS may correspond to a front surface of the electronic device ED, and simultaneously correspond to a front surface of a window WM. Hereinafter, the display surface FS of the electronic device ED and the front surface FS of the window WM will be denoted as the same reference numerals or symbols.

The electronic device ED according to an embodiment may sense the external input TC applied from the outside. The external input TC may include various types of inputs such as force, pressure, temperature, or light. In this embodiment, the external input TC is illustrated as a user's hand applied to the front surface of the electronic device ED. However, this is exemplarily illustrated, and the external input TC may include an input, such as contact by a pen or hovering, applied by approaching the electronic device ED.

The electronic device ED may sense a user's input through the display surface FS defined on the front surface, and respond to the sensed input signal. However, a region, of the electronic device ED, which senses the external input TC is not limited to the front surface of the electronic device ED, and may vary depending on a design of the electronic device ED. For example, the electronic device ED may also sense a user's input applied to a side surface or a rear surface of the electronic device ED.

The electronic device ED may include the window WM, a display module DM, an electronic module ELM, a power module PM, and a housing HAU. The window WM may be coupled to the housing HAU to constitute an exterior of the electronic device ED.

The window WM may be disposed on the display module DM. The window WM may cover a front surface IS of the display module DM and protect the display module DM from an external impact and scratches. The window WM may be coupled to the display module DM through an adhesive layer.

The window WM may include an optically transparent insulating material. For example, the window WM may include glass or a synthetic resin as a base film. The window WM may have a single- or multi-layered structure. For example, the window WM with the multi-layered structure may include synthetic resin films which are coupled by an adhesive, or a glass film and a synthetic resin film which are coupled by an adhesive. The window WM may further include a functional layer, such as an anti-fingerprint layer, a phase control layer, and a hard coating layer, disposed on the transparent base film.

The front surface FS of the window WM may correspond to the front surface FS of the electronic device ED. The front surface FS of the window WM may include a transmission region TA and a bezel region BZA.

The transmission region TA may be an optically transparent region. The transmission region TA may transmit the image IM provided by the display module DM. In this embodiment, the transmission region TA is illustrated as a quadrangular shape, but is not limited thereto. The transmission region TA may have various shapes.

The bezel region BZA may be a region having lower light transmittance than the transmission region TA. The bezel region BZA may correspond to a region printed with a material having a color. The bezel region BZA may prevent light transmission, and thus prevent one component of the display module DM disposed overlapping the bezel region BZA from being visible from the outside.

The bezel region BZA may be adjacent to the transmission region TA. The shape of the transmission region TA may be substantially defined by the bezel region BZA. For example, the bezel region BZA may be disposed outside the transmission region TA, and may surround the transmission region TA. However, this is exemplarily illustrated, and the bezel region BZA may be adjacent to only one side of the transmission region TA, or may be disposed on the side surface, not the front surface, of the electronic device ED. In addition, the bezel region BZA may also be omitted.

The display module DM may be disposed between the window WM and the housing HAU. The display module DM may display the image IM, and may sense the external input TC. The image IM may be displayed on the front surface IS of the display module DM. The front surface IS of the display module DM may include an active region AA and a peripheral region NAA.

The active region AA may be activated in response to an electrical signal. For example, the active region AA may be a region where the image IM is displayed, and simultaneously a region where the external input TC is sensed. The active region AA may overlap at least a portion of the transmission region TA. Accordingly, the user may view the image IM or provide the external input TC, through the transmission region TA. However, this is an example, and within the active region AA, a region where the image IM is displayed may also be separated from the region where the external input TC is sensed. The above configuration is not limited to any one embodiment.

The peripheral region NAA may be adjacent to the active region AA. For example, the peripheral region NAA may surround the active region AA. A drive circuit, drive wiring, or the like for driving the active region AA may be disposed in the peripheral region NAA. The peripheral region NAA may overlap at least a portion of the bezel region BZA, and components disposed in the peripheral region NAA may be prevented from being visible from the outside by the bezel region BZA.

The display module DM may include a display panel and an input sensing unit. The display panel may display the image IM, and the input sensing unit may sense the external input TC. A detailed description thereof will be given later.

A portion of the display module DM may be bent with respect to a bending axis extending in the first direction DR1. That is, the portion of the display module DM may be bent toward the rear surface of the display module DM corresponding to the active region AA. A flexible circuit board FCB may be connected to the bent portion of the display module DM, and accordingly, the flexible circuit board FCB may overlap the display module DM on a plane.

The flexible circuit board FCB may be electrically connected to the display module DM at one side of the display module DM. The flexible circuit board FCB may generate an electrical signal to be provided to the display module DM, or may receive a signal generated from the display module DM and calculate a result value that includes information about the intensity or location where the external input TC is sensed.

The electronic module ELM and the power module PM may be disposed under the display module DM. The electronic module ELM and the power module PM may be electrically connected through a separated circuit board.

The power module PM may supply power necessary for an operation of the electronic device ED. For example, the power module PM may include a typical battery module.

The electronic module ELM may include various functional modules for operating the electronic device ED. For example, the electronic module ELM may include a control module, wireless communication module, image input module, sound input module, sound output module, memory, optical module, external interface module, and the like. The electronic module ELM may include a main circuit board, and the modules of the electronic module ELM may be mounted on the main circuit board, or electrically connected to the main circuit board through a separate circuit board.

The control module of the electronic module ELM may control overall operations of the electronic device ED. For example, the control module may activate or deactivate the display module DM in accordance with a user's input. The control module may include at least one microprocessor. The optical module of the electronic module ELM may include a camera module, a proximity sensor, a biometric sensor which recognizes a part of user body (for example, a fingerprint, iris, or face), a lamp which emits light, or the like.

The housing HAU may be coupled to the window WM to provide an internal space accommodating the display module DM, the electronic module ELM, the power module PM, and the flexible circuit board FCB. The housing HAU may include a material with relatively high rigidity. For example, the housing HAU may include a plurality of frames and/or plates that contain glass, plastic, or metal, or that are composed of a combination thereof. The housing HAU may protect the components of the electronic device ED accommodated in the housing HAU by absorbing an impact applied from the outside, or preventing foreign matters/moisture from being infiltrated from the outside.

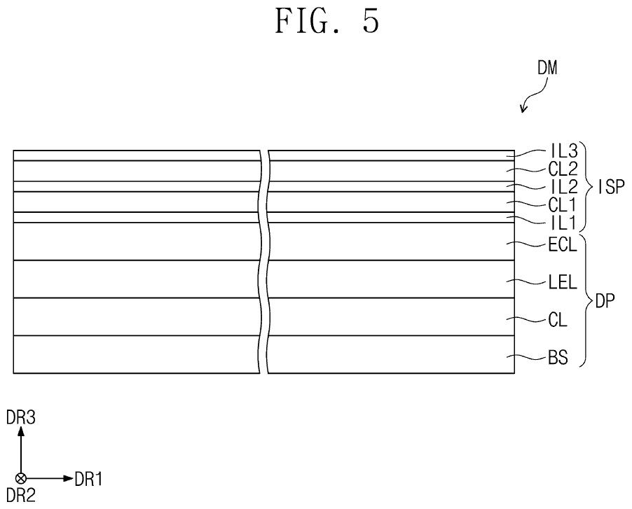

FIG. 5 is a cross-sectional view of a display module according to an embodiment of the inventive concept.

Referring to FIG. 5, a display module DM may include a display panel DP and an input sensing unit ISP. The input sensing unit ISP may be disposed on the display panel DP. For example, the input sensing unit ISP may be directly disposed on the display panel DP. In this embodiment, the wording “the input sensing unit ISP is directly disposed on the display panel DP.” means that the input sensing unit ISP is formed on the display panel DP through a continuous process, and thus the input sensing unit ISP and the display panel DP are coupled without a separate adhesive layer. That is, components of the input sensing unit ISP may be formed on a base surface that the display panel DP provides.

The display panel DP may display an image in response to an electrical signal. The display panel DP according to an embodiment may be an emissive display panel, but is not particularly limited thereto. For example, the display panel DP may be an organic light-emitting display panel, an inorganic light-emitting display panel, or a quantum dot light-emitting display panel. A light-emitting layer of the organic light-emitting display panel may include an organic light-emitting material, and a light-emitting layer of the inorganic light-emitting display panel may include an inorganic light-emitting material. A light-emitting layer of the quantum dot light-emitting display panel may include quantum dots, quantum rods, and the like. Hereinafter, the display panel DP is described as an organic light-emitting display panel.

The display panel DP may include a base substrate BS, a circuit element layer CL, a light-emitting element layer LEL, and an encapsulation layer ECL which are sequentially stacked along a third direction DR3.

The base substrate BS may be a rigid substrate or a flexible substrate that is capable of bending, folding, rolling, or the like. For example, the base substrate BS may be a glass substrate, a metal substrate, a polymer substrate, or the like. The base substrate BS may provide a base surface where the circuit element layer CL is disposed.

The base substrate BS may include an inorganic layer, an organic layer, or a composite material layer. The base substrate BS may have a single- or multi-layered structure. For example, the base substrate BS with the multi-layered structure may include synthetic resin layers and a multi- or single-layered inorganic layer disposed between the synthetic resin layers. The synthetic resin layer may include an acrylate-based resin, a methacrylate-based resin, polyisoprene, a vinyl-based resin, an epoxy-based resin, a urethane-based resin, a cellulose-based resin, a siloxane-based resin, a polyamide-based resin, a perylene-based resin, or the like, but the material of the synthetic resin layer is not limited thereto.

The circuit element layer CL may be disposed on the base substrate BS. The circuit element layer CL may include at least one insulation layer, a semiconductor pattern, and a conductive pattern. The insulation layer, semiconductor pattern, and conductive pattern included in the circuit element layer CL may form drive elements such as a transistor, signal lines, and pads.

The light-emitting element layer LEL may be disposed on the circuit element layer CL. The light-emitting element layer LEL may include light-emitting elements each of which emits light. For example, the light-emitting elements may include an organic light-emitting element, an inorganic light-emitting element, a micro LED, a nano LED, or the like. The light-emitting elements of the light-emitting element layer LEL may be electrically connected to the drive elements of the circuit element layer CL, and may emit light in response to an electrical signal provided by the drive elements.

The encapsulation layer ECL may be disposed on the light-emitting element layer LEL, and may seal the light-emitting elements. The encapsulation layer ECL may include at least one thin film so as to improve optical efficiency of the light-emitting element layer LEL, or to protect the light-emitting element layer LEL. For example, the encapsulation layer ECL may include at least one among an inorganic film and an organic film. The inorganic film of the encapsulation layer ECL may protect the light-emitting elements from moisture/oxygen. The organic film of the encapsulation layer ECL may protect the light-emitting elements from foreign matters such as dust particles.

The input sensing unit ISP may sense an external input, and provide an input signal including information about the external input such that the display panel DP may display an image corresponding to the external input. The input sensing unit ISP may be driven in various manners such as a capacitive manner, resistive manner, infrared manner, sonic manner, or pressure manner, and a driving manner of the input sensing unit ISP is not limited to any one manner as long as the input sensing unit is capable of sensing an external input. In this embodiment, the input sensing unit ISP is described as an input sensing panel driven in the capacitive manner.

The input sensing unit ISP may include a base layer IL1, a first sensing conductive layer CL1, a first sensing insulation layer IL2, a second sensing conductive layer CL2, and a second sensing insulation layer IL3 which are sequentially stacked along the third direction DR3. The base layer IL1 of the input sensing unit ISP may be in contact with the encapsulation layer ECL. However, an embodiment of the inventive concept is not limited thereto, and at least one of the base layer IL1 or the second sensing insulation layer IL3 may be omitted.

Each of the first sensing conductive layer CL1 and the second sensing conductive layer CL2 may have a single- or multi-layered structure. The conductive layer with the multi-layered structure may include at least two among transparent conductive layers and metal layers. The conductive layer with the multi-layered structure may include metal layers containing different metals. The transparent conductive layer may include at least one among indium tin oxide (ITO), indium zinc oxide (IZO), zinc oxide (ZnO), indium tin zinc oxide (ITZO), PEDOT, metal nanowire, and graphene. The metal layer may include at least one among molybdenum, silver, titanium, copper, aluminum, and an alloy thereof. For example, each of the first sensing conductive layer CL1 and the second sensing conductive layer CL2 may have a second-layer structure, for example, a second-layer structure of ITO/copper, but is not limited thereto, and may have a three-layer structure of titanium/aluminum/titanium.

The first sensing conductive layer CL1 and the second sensing conductive layer CL2 may each include sensing conductive patterns. The sensing conductive patterns of the first sensing conductive layer CL1 and the second sensing conductive layer CL2 may form sensing electrodes, which constitute the input sensing unit ISP, and sensing lines connected to thereto.

The base layer IL1, the first sensing insulation layer IL2, and the second sensing insulation layer IL3 may each include at least one among an inorganic film and an organic film. For example, the inorganic film may include at least one among aluminum oxide, titanium oxide, silicon oxide, silicon oxynitride, zirconium oxide, and hafnium oxide, and the organic film may include at least one among an acrylate-based resin, a methacrylate-based resin, polyisoprene, a vinyl-based resin, an epoxy-based resin, a urethane-based resin, a cellulose-based resin, a siloxane-based resin, a polyimide-based resin, a polyamide-based resin, and a perylene-based resin. However, the materials of the inorganic film and the organic film are not limited to the above examples. In an embodiment, the base layer IL1 may include the inorganic film, and the first sensing insulation layer IL2 and the second sensing insulation layer IL3 may include the organic film, but an embodiment of the inventive concept is not limited thereto.

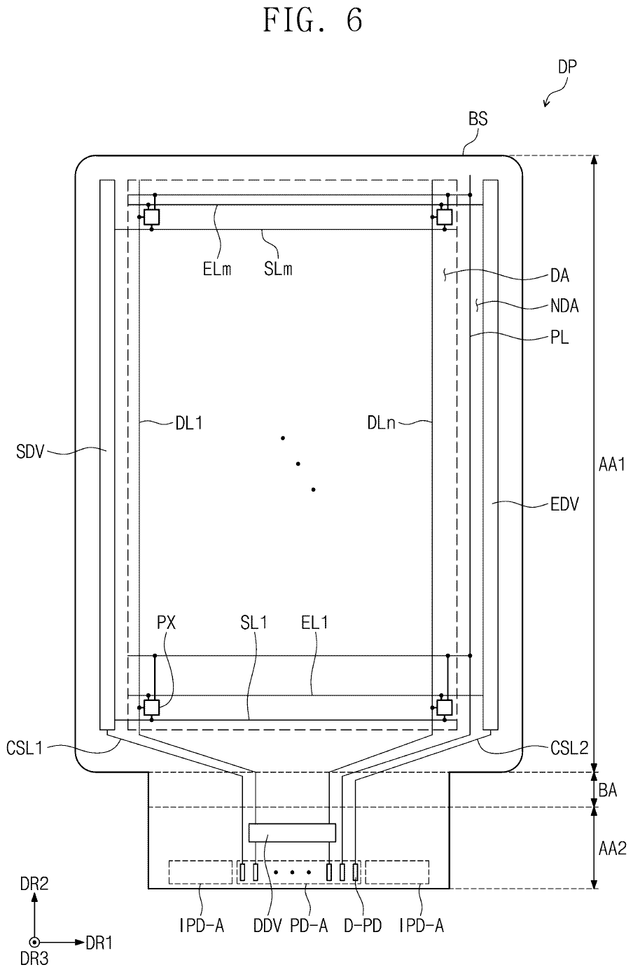

FIG. 6 is a plan view of a display panel according to an embodiment of the inventive concept.

Referring to FIG. 6, a display panel DP may include a base substrate BS, pixels PX, signal lines SL1 to SLm, DL1 to DLn, EL1 to ELm, CSL1, CSL2, and PL electrically connected to the pixels PX, a scan driver SDV, an emission driver EDV, a data driver DDV, and display pads D-PD.

The base substrate BS may provide a base surface where electrical elements, lines, and the like of the display panel DP are disposed. The base substrate BS may include a first base region AA1, a bending region BA, and a second base region AA2 which are separated in a second direction DR2. The bending region BA may extend from the first base region AA1 in the second direction DR2. The second base region AA2 may extend from the bending region BA in the second direction DR2. Accordingly, the first base region AA1 and the second base region AA2 may be spaced apart from each other with the bending region BA therebetween.

The first base region AA1 may include a display region DA. The display region DA may be a region where light-emitting elements of the pixels PX are disposed. Accordingly, the pixels PX may display an image through the display region DA. The display region DA may correspond to the active region AA (see FIG. 4) of the display module DM (see FIG. 4), and may overlap the transmission region TA (see FIG. 4) of the window WM (see FIG. 4).

A remaining region of the first base region AA1 except the display region DA, the bending region BA, and the second base region AA2 may be defined as a non-display region NDA. The non-display region NDA may be adjacent to the display region DA and may be a region where an image is not displayed. The non-display region NDA may surround the display region DA. In the non-display region NDA, the scan driver SDV, the emission driver EDV, and the data driver DDV for driving the pixels PX, and the display pads D-PD electrically connected to the signal lines SL1 to SLm, DL1 to DLn, EL1 to ELm, CSL1, CSL2, and PL may be disposed. The signal lines SL1 to SLm, DL1 to DLn, EL1 to ELm, CSL1, CSL2, and PL electrically connected to the pixels PX may extend and be disposed on the non-display region NDA.

The bending region BA may be a region that is bent with respect to a bending axis extending in a first direction DR1. That is, the bending region BA may be bent toward a rear surface of the display panel DP corresponding to the first base region AA1. The second base region AA2 extending from one side of the bending region BA may overlap the first base region AA1 on a plane, according to the bending of the bending region BA. That is, the second base region AA2 may be disposed on the rear surface of the display panel DP corresponding to the first base region AA1.

A width of each of the bending region BA and the second base region AA2 in the first direction DR1 may be smaller than a width of the first base region AA1. Since the bending region BA has a smaller width than the first base region AA1 in a direction parallel to the bending axis, the bending region BA may be easily bent. However, this is exemplarily illustrated. At least one of the widths of the bending region BA and the second base region AA2 in the first direction DR1 may be the same as the width of the first base region AA1, and is not limited to any one embodiment.

The second base region AA2 may be a region that is located under the first base region AA1 by the bending of the bending region BA to be flatly provided. The second base region AA2 may be a region where the data driver DDV and signal lines, among the signal lines SL1 to SLm, DL1 to DLn, EL1 to ELm, CSL1, CSL2, and PL, extending toward the display pads D-PD via the bending region BA are disposed.

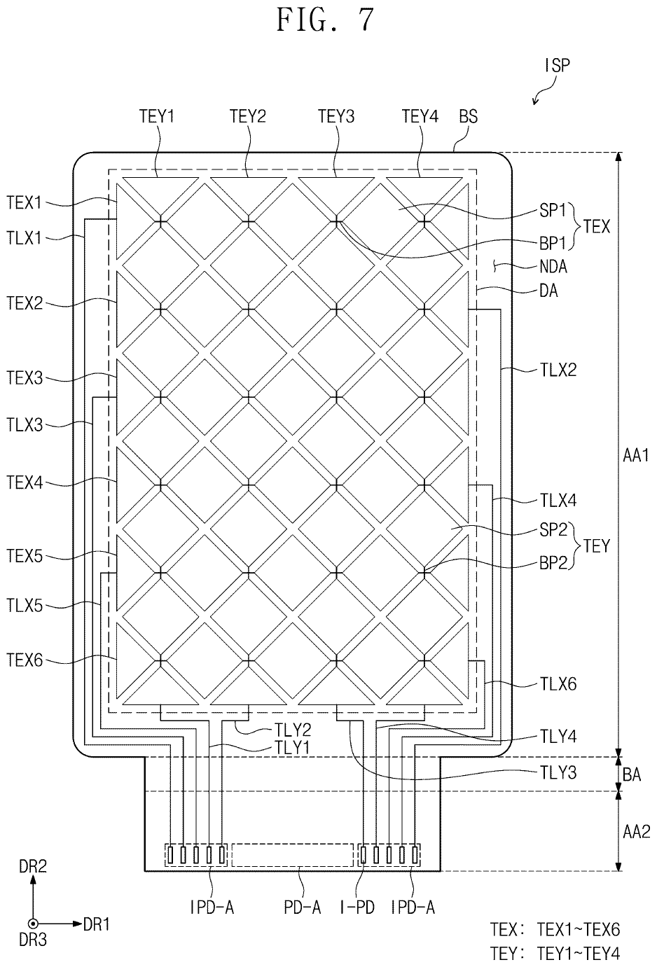

A region where the display pads D-PD are disposed and a region where sensing pads I-PD (see FIG. 7) to be described later are disposed may be respectively distinguished as a display pad region PD-A and a sensing pad region IPD-A. FIG. 6 exemplarily illustrates that the display pad region PD-A and the sensing pad region IPD-A are separated in the first direction DR1. For example, the sensing pad region IPD-A may be provided while being adjacent to two sides of the second base region AA2 in the first direction DR1, and the display pad region PD-A may be provided in a central part. However, an embodiment of the inventive concept is not necessarily limited thereto, and the locations where the display pads D-PD and the sensing pads I-PD (see FIG. 7) are disposed may be variously changed.

The flexible circuit board FCB (see FIG. 4) may be disposed on the second base region AA2, where the display pads D-PD and the sensing pads I-PD (see FIG. 7) are disposed, to be electrically connected to the display pads D-PD and the sensing pads I-PD (see FIG. 7). The flexible circuit board FCB (see FIG. 4) disposed adjacent to a lower end of the second base region AA2 may be located on the rear surface of the display panel DP according to the bending of the bending region BA. On a front surface of the electronic device ED (see FIG. 4), the second base region AA2 and the flexible circuit board FCB (see FIG. 4) may be located under the first base region AA1, thereby reducing a bezel area of the electronic device ED (see FIG. 4).

The pixels PX may each include a pixel driving circuit, which is composed of transistors (for example, a switching transistor, driving transistor, etc.) and at least one capacitor, and a light-emitting element electrically connected to the pixel driving circuit. The pixels PX may generate light in response to an electrical signal applied to each of the pixels PX, and may display an image through the display region DA. According to an embodiment, some of the pixels PX may include a transistor disposed in the non-display region NDA, and the above configuration is not limited to any one embodiment.

The scan driver SDV and the emission driver EDV may be disposed in the non-display region NDA corresponding to the first base region AA1. The data driver DDV may be disposed in the non-display region NDA corresponding to the second base region AA2. In an embodiment, the data driver DDV may be provided as a form of an integrated circuit chip mounted within the non-display region NDA of the display panel DP. However, an embodiment of the inventive concept is not limited thereto, and the data driver DDV may also be mounted on the flexible circuit board FCB (see FIG. 4).

The signal lines SL1 to SLm, DL1 to DLn, EL1 to ELm, CSL1, CSL2, and PL may include scan lines SL1 to SLm, data lines DL1 to DLn, emission lines EL1 to ELm, first and second control lines CSL1 and CSL2, and a power line PL. Here, m and n represent natural numbers.

The data lines DL1 to DLn may be insulated from the scan lines SL1 to SLm and the emission lines EL1 to ELm, and may cross the scan lines and the emission lines. For example, the scan lines SL1 to SLm may extend in the first direction DR1 to be electrically connected to the scan driver SDV. The data lines DL1 to DLn may extend in the second direction DR2 to be electrically connected to the data driver DDV. The emission lines EL1 to ELm may extend in the first direction DR1 to be electrically connected to the emission driver EDV.

The power line PL may include a portion extending in the first direction DR1 and a portion extending in the second direction DR2. The portion, extending in the first direction DR1, and the portion, extending in the second direction DR2, of the power line PL may be disposed on different layers, or may be integrally disposed at a same layer. The portion, extending in the first direction DR1, of the power line PL may be electrically connected to the pixels PX and the portion extending in the second direction DR2. The portion, extending in the second direction DR2, of the power line PL may be disposed in the non-display region NDA, and may be electrically connected to the display pads D-PD via the bending region BA and the second base region AA2, from the first base region AA1. The power line PL may provide a power voltage to the pixels PX.

The first control line CSL1 may be electrically connected to the scan driver SDV, and may extend toward the lower end of the second base region AA2 via the bending region BA. The second control line CSL2 may be electrically connected to the emission driver EDV, and may extend toward the lower end of the second base region AA2 via the bending region BA.

The display pads D-PD may be disposed adjacent to the lower end of the second base region AA2. On the second base region AA2, the display pads D-PD may be disposed more adjacent to a lower end of the base substrate BS than the data driver DDV. The display pads D-PD may be arranged to be spaced apart from each other along the first direction DR1. The power line PL, the first control line CSL1, and the second control line CSL2 may each be electrically connected to a corresponding display pad D-PD of the display pads D-PD. The data lines DL1 to DLn may each be electrically connected to a corresponding display pad D-PD of the display pads D-PD through the data driver DDV.

The display pads D-PD may be electrically connected to the flexible circuit board FCB (see FIG. 4) through an adhesive layer, and an electrical signal provided from the flexible circuit board FCB (see FIG. 4) may be transmitted to the display panel DP through the display pads D-PD. However, a connection method between the display pads D-PD and the flexible circuit board FCB (see FIG. 4) is not limited thereto.

The scan driver SDV may generate scan signals in response to a scan control signal. The scan signals may be applied to the pixels PX through the scan lines SL1 to SLm. The data driver DDV may generate data voltages corresponding to image signals in response to a data control signal. The data voltages may be applied to the pixels PX through the data lines DL1 to DLn. The emission driver EDV may generate emission signals in response to an emission control signal. The emission signals may be applied to the pixels PX through the emission lines EL1 to ELm.

The pixels PX may receive the data voltages in response to the scan signals. The pixels PX may generate an image by emitting light of luminance corresponding to the data voltages in response to the emission signals. The emission time of the pixels PX may be controlled by the emission signals.

FIG. 7 is a plan view of an input sensing unit according to an embodiment of the inventive concept. For convenience of explanation, FIG. 7 briefly illustrates components of an input sensing unit ISP disposed on the aforementioned base substrate BS.

In an embodiment, the input sensing unit ISP may be operated by a mutual capacitive manner. Referring to FIG. 7, the input sensing unit ISP may include first sensing electrodes TEX: TEX1 to TEX6, second sensing electrodes TEY: TEY1 to TEY4, first sensing lines TLX1 to TLX6, second sensing lines TLY1 to TLY4, and sensing pads I-PD. However, an embodiment of the inventive concept is not limited thereto, and the input sensing unit ISP may be operated by a self-capacitive manner.

The first sensing electrodes TEX may each extend along a first direction DR1, and the first sensing electrodes TEX may be arranged along a second direction DR2. FIG. 7 exemplarily illustrates six first sensing electrodes TEX1 to TEX6. However, the number of the first sensing electrodes TEX included in the input sensing unit ISP is not limited thereto. One first sensing electrode TEX may include first sensing patterns SP1 arranged along the first direction DR1 and first connection patterns BP1 for connecting the first sensing patterns.

The second sensing electrodes TEY may each extend along the second direction DR2, and the second sensing electrodes TEY may be arranged along the first direction DR1. FIG. 7 exemplarily illustrates four second sensing electrodes TEY1 to TEY4. However, the number of the second sensing electrodes TEY included in the input sensing unit ISP is not limited thereto. One second sensing electrode TEY may include second sensing patterns SP2 arranged along the second direction DR2, and second connection patterns BP2 for connecting the second sensing patterns.

The first sensing electrodes TEX and the second sensing electrodes TEY may be electrically insulated. The input sensing unit ISP may sense an external input through a change in capacitance between the first sensing electrodes TEX and the second sensing electrodes TEY. The first sensing electrodes TEX and the second sensing electrodes TEY may be disposed in a region corresponding to a display region DA of the base substrate BS. Accordingly, the electronic device ED (see FIG. 3) may simultaneously sense an external input applied to the display region DA while displaying an image through the display region DA.

The first sensing lines TLX1 to TLX6 may be disposed on a non-display region NDA to be respectively electrically connected to the first sensing electrodes TEX1 to TEX6. Some of the first sensing lines TLX1 to TLX6 may be disposed on a left side of the non-display region NDA, and remaining parts may be disposed on a right side of the non-display region NDA. For example, the first sensing lines TLX1, TLX3, and TLX5 connected to the first sensing electrodes TEX1, TEX3, and TEX5 disposed in odd rows may be respectively connected to left sides of the first sensing electrodes TEX1, TEX3, and TEX5, and the first sensing lines TLX2, TLX4, and TLX6 connected to the first sensing electrodes TEX2, TEX4, and TEX6 disposed in even rows may be respectively connected to right sides of the first sensing electrodes TEX2, TEX4, and TEX6. However, an arrangement of the first sensing lines TLX1 to TLX6 is not limited thereto, and the first sensing lines TLX1 to TLX6 may all be disposed on the left side of the non-display region NDA, or the first sensing lines TLX1 to TLX6 may all be disposed on the right side of the non-display region NDA.

The first sensing lines TLX1 to TLX6 may each extend toward a second base region AA2 via a bending region BA, from a first base region AA1. The first sensing lines TLX1 to TLX6 may be respectively electrically connected to the sensing pads I-PD disposed on the second base region AA2.

The second sensing lines TLY1 to TLY4 may be disposed on the non-display region NDA to be respectively electrically connected to the second sensing electrodes TEY1 to TEY4. Some of the second sensing lines TLY1 to TLY4 may be disposed adjacent to the left side of the non-display region NDA, and remaining parts may be disposed adjacent to the right side of the non-display region NDA. For example, in the first direction DR1, the second sensing lines TLY1 and TLY2, which are electrically connected to the second sensing electrodes TEY1 and TEY2, among the second sensing electrodes TEY1 to TEY4, disposed on the left side, may be disposed adjacent to a left side of the first base region AA1, and the second sensing lines TLY3 and TLY4, which are electrically connected to the second sensing electrodes TEY3 and TEY4 disposed on the right side, may be disposed adjacent to a right side of the first base region AA1. However, an arrangement of the second sensing lines TLY1 to TLY4 is not limited thereto.

The second sensing lines TLY1 to TLY4 may each extend toward the second base region AA2 via the bending region BA, from a region adjacent to a lower end of the first base region AA1. The second sensing lines TLY1 to TLY4 may be respectively electrically connected to the sensing pads I-PD disposed on the second base region AA2.

Some of the sensing pads I-PD may be disposed in a region adjacent to a left side of the second base region AA2 in the first direction DR1, and remaining parts may be disposed in a region adjacent to a right side of the second base region AA2. For example, the sensing pads I-PD may be divided into two groups which are spaced apart from each other with a display pad region PD-A therebetween. However, an arrangement of the sensing pads I-PD is not limited thereto.

The sensing pads I-PD may be disposed at a same layer as the display pads D-PD (see FIG. 6). The sensing pads I-PD may be disposed on a different layer from the first and second sensing lines TLX1 to TLX6 and TLY1 to TLY4 to be connected to the first and second sensing lines through a contact hole. However, an embodiment of the inventive concept is not limited thereto, and the sensing pads I-PD may also be disposed on a different layer from the display pads D-PD (see FIG. 6). For example, the sensing pads I-PD may be integrally formed with the first and second sensing lines TLX1 to TLX6 and TLY1 to TLY4 at a same layer.

The first and second sensing lines TLX1 to TLX6 and TLY1 to TLY4 may be disposed above the components of the display panel DP (see FIG. 6), on a region corresponding to the non-display region NDA of the base substrate BS. Accordingly, the first and second sensing lines TLX1 to TLX6 and TLY1 to TLY4 may overlap the components of the display panel DP (see FIG. 6) on the bending region BA and the second base region AA2.

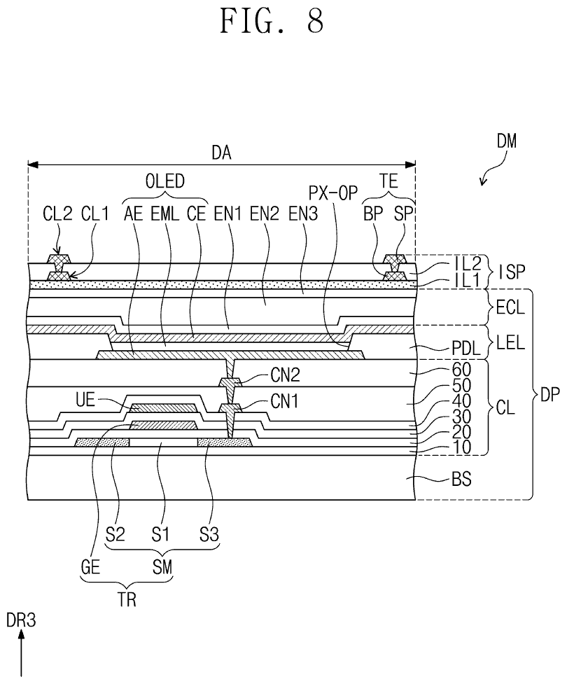

FIG. 8 is a cross-sectional view of a display module according to an embodiment of the inventive concept. FIG. 8 exemplarily illustrates a cross section of the pixel PX (see FIG. 6) disposed in a display region DA.

Referring to FIG. 8, a display module DM may include a display panel DP and an input sensing unit ISP disposed on the display panel DP. The above description may be equally applied to each component.

As above described with reference to FIG. 5, the display panel DP may include a base substrate BS, a circuit element layer CL, a light-emitting element layer LEL, and an encapsulation layer ECL.

The base substrate BS may have an insulating property, and provide a base surface where components of the display module DM are disposed. The base substrate BS may have flexibility to allow bendability. As mentioned above, the base substrate BS may include the first base region AA1 (see FIG. 6), the bending region BA (see FIG. 6), and the second base region AA2 (see FIG. 6), and the bending region BA (see FIG. 6) of the base substrate BS may be bent to have a curvature.

The circuit element layer CL may include insulation layers 10 to 60 disposed on the base substrate BS, a transistor TR of the pixel PX (see FIG. 6), an upper electrode UE, and connection electrodes CN1 and CN2. The insulation layers 10 to 60 may include first to sixth insulation layers 10 to 60 sequentially stacked along a thickness direction on the base substrate BS. However, an embodiment of the insulation layers 10 to 60 included in the circuit element layer CL is not limited thereto, and may vary depending on a component or a manufacturing process of the circuit element layer CL.

The first insulation layer 10 may be disposed on the base substrate BS. The first insulation layer 10 may be provided as a barrier layer and/or buffer layer for preventing foreign matters from being introduced from the outside. The first insulation layer 10 may improve bonding force between the base substrate BS and a semiconductor pattern SM and/or a conductive pattern, of the circuit element layer CL. The first insulation layer 10 may include at least one among a silicon oxide layer and a silicon nitride layer. In an embodiment, the first insulation layer 10 may include silicon oxide layers and silicon nitride layers alternately stacked.

The pixel PX (see FIG. 6) may be disposed on the base substrate BS. The pixel PX (see FIG. 6) may be disposed corresponding to the display region DA. The pixel PX (see FIG. 6) may include the transistor TR and a light-emitting element OLED.

The transistor TR may include the semiconductor pattern SM and a gate electrode GE. The semiconductor pattern SM may be disposed on the first insulation layer 10. The semiconductor pattern SM may include a channel S1, a source S2, and a drain S3. The semiconductor pattern SM may include a silicon semiconductor, and may include a single crystal silicon semiconductor, polysilicon semiconductor, or amorphous silicon semiconductor. An embodiment of the inventive concept is not limited thereto, and the semiconductor pattern SM may also include an oxide semiconductor. The semiconductor pattern SM according to an embodiment of the inventive concept may be formed from various materials as long as the semiconductor pattern SM has a semiconductor property, and is not limited to any one embodiment.

The semiconductor pattern SM may include a plurality of regions with different electrical properties depending on whether or not doped or reduced. For example, the semiconductor pattern SM may include a high conductive region by being doped or reducing metal oxide, and the high conductive region may serve as an electrode or signal wiring of the transistor TR, which may correspond to the source S2 and the drain S3 of the transistor TR. The semiconductor pattern SM may include a region with relatively low conductivity by being undoped, which may correspond to the channel S1 (or an active) of the transistor TR.

The second insulation layer 20 may be disposed on the first insulation layer 10 to cover the semiconductor pattern SM. The gate electrode GE may be disposed on the second insulation layer 20. The second insulation layer 20 may be disposed between the semiconductor pattern SM and the gate electrode GE, of the transistor TR. The gate electrode GE may overlap the channel S1 of the semiconductor pattern SM on a plane. The gate electrode GE may function as a mask during a doping process of the semiconductor pattern SM. The gate electrode GE may include molybdenum (Mo), an alloy containing molybdenum, titanium (Ti), an alloy containing titanium, etc. which have heat resistance, but is not limited thereto.

A configuration of the transistor TR illustrated in FIG. 8 is an example, and the source S2 or drain S3 of the transistor TR may also be electrodes independently formed from the semiconductor pattern SM. In this case, the source S2 and drain S3 may be in contact with the semiconductor pattern SM, or may be connected to the semiconductor pattern SM by passing through the insulation layer. In addition, gate electrode GE may also be disposed under the semiconductor pattern SM. The transistor TR according to an embodiment of the inventive concept may be formed into various configurations, and is not limited to any one embodiment.

The second insulation layer 20 and the third to sixth insulation layers 30 to 60 to be described later may include at least one among an inorganic layer and an organic layer. For example, the inorganic layer may include at least one among aluminum oxide, titanium oxide, silicon oxide, silicon oxynitride, zirconium oxide, and hafnium oxide. The organic layer may include at least one among an acrylate-based resin, a methacrylate-based resin, polyisoprene, a vinyl-based resin, an epoxy-based resin, a urethane-based resin, a cellulose-based resin, a siloxane-based resin, a polyamide-based resin, and a perylene-based resin.

The third insulation layer 30 may be disposed on the second insulation layer 20, and may cover the gate electrode GE. The upper electrode UE may be disposed on the third insulation layer 30. The upper electrode UE may overlap the gate electrode GE on a plane, and the gate electrode GE and the upper electrode UE which overlap each other may form a capacitor.

The fourth insulation layer 40 may be disposed on the third insulation layer 30, and may cover the upper electrode UE. The connection electrodes CN1 and CN2 may include a first connection electrode CN1 and a second connection electrode CN2. The first connection electrode CN1 may be disposed on the fourth insulation layer 40. The fifth insulation layer 50 may be disposed on the fourth insulation layer 40 to cover the first connection electrode CN1. The second connection electrode CN2 may be disposed on the fifth insulation layer 50. The sixth insulation layer 60 may be disposed on the fifth insulation layer 50 to cover the second connection electrode CN2. In an embodiment, at least one among the fifth insulation layer 50 and the sixth insulation layer 60 may include the organic layer, and may provide a flat upper surface while covering a stepped portion between the components disposed thereunder.

The first connection electrode CN1 may be electrically connected to the semiconductor pattern SM through a contact hole that penetrates the second to fourth insulation layers 20 to 40. The second connection electrode CN2 may be electrically connected to the first connection electrode CN1 through a contact hole that penetrates the fifth insulation layer 50.

The first connection electrode CN1 and the second connection electrode CN2 may each include a conductive material. The first connection electrode CN1 and the second connection electrode CN2 may each include gold, silver, copper, aluminum, platinum, molybdenum, titanium, an alloy thereof, and the like. At least one among the first connection electrode CN1 and the second connection electrode CN2 may include conductive layers in a multi-layered structure. For example, at least one among the first connection electrode CN1 and the second connection electrode CN2 may have a three-layer structure of titanium/aluminum/titanium. However, an embodiment of the inventive concept is not limited thereto.

At least one among the first connection electrode CN1 and the second connection electrode CN2 may be omitted, according to an embodiment of the circuit element layer CL. Alternatively, an additional connection electrode for connecting the transistor TR and the light-emitting element OLED may further be disposed, according to an embodiment of the circuit element layer CL. An electrical connection method between the light-emitting element OLED and the transistor TR may be variously changed depending on the number of the insulation layers disposed between the light-emitting element OLED and the transistor TR, and is not limited to any one embodiment.

The light-emitting element layer LEL may include the light-emitting element OLED and a pixel-defining film PDL. The light-emitting element OLED and the pixel-defining film PDL may be disposed on the sixth insulation layer 60. The light-emitting element OLED may include a first electrode AE, a light-emitting layer EML, and a second electrode CE.

The first electrode AE may be electrically connected to the second connection electrode CN2 through a contact hole that penetrates the sixth insulation layer 60. The first electrode AE may be electrically connected to the transistor TR through the first and second connection electrodes CN1 and CN2.

In the pixel-defining film PDL, a pixel opening PX-OP which exposes at least a portion of the first electrode AE may be defined. One region, of the first electrode AE, exposed from the pixel-defining film PDL may correspond to a light-emitting region. The pixel-defining film PDL may include an inorganic layer, an organic layer, or a composite material layer. According to an embodiment, the pixel-defining film PDL may further include black pigment or black dye.

The light-emitting layer EML may be disposed on the first electrode AE. The light-emitting layer EML may provide a color light. The light-emitting layer EML may be disposed corresponding to the pixel opening PX-OP defined in the pixel-defining film PDL. The light-emitting element OLED and the pixel opening PX-OP may be provided in plurality, and the light-emitting layers EML of the light-emitting elements OLED may be disposed respectively corresponding to the pixel openings PX-OP and provided in a form of a spaced pattern. However, an embodiment of the inventive concept is not limited thereto, and the light-emitting layers EML of the light-emitting elements OLED may also be integrally formed into a common layer.

The second electrode CE may be disposed on the light-emitting layer EML and the pixel-defining film PDL. The second electrode CE may be provided as a common electrode that is disposed in the pixels PX (see FIG. 6) in common.

The light-emitting element OLED may further include at least any one among a hole control region disposed between the first electrode AE and the light-emitting layer EML and an electron control region disposed between the light-emitting layer EML and the second electrode CE. The hole control region may include at least one among a hole generation layer, a hole transport layer, and an electron blocking layer, and the electron control region may include at least one among an electron generation layer, an electron transport layer, and a hole blocking layer.

The encapsulation layer ECL may be disposed on the light-emitting element layer LEL. The encapsulation layer ECL may be disposed on the light-emitting element OLED and the pixel-defining film PDL, and may seal the light-emitting element OLED. The encapsulation layer ECL may include at least one among an inorganic film and an organic film. In this embodiment, the encapsulation layer ECL may include a first inorganic film EN1, a second inorganic film EN3, and an organic film EN2 disposed between the first and second inorganic films EN1 and EN3. However, a configuration of the encapsulation layer ECL is not limited thereto as long as the encapsulation layer is capable of sealing the light-emitting element OLED.

The first inorganic film EN1 may be disposed on the second electrode CE, and the organic film EN2 and the second inorganic film EN3 may be sequentially disposed on the first inorganic film EN1 in a thickness direction of the display panel DP. The first and second inorganic films EN1 and EN3 may protect the light-emitting element OLED from moisture or oxygen introduced from the outside. For example, the first and second inorganic films EN1 and EN3 may each include at least one among silicon nitride, silicon oxynitride, silicon oxide, titanium oxide, and aluminum oxide. However, the material of the first and second inorganic films EN1 and EN3 is not limited to the above examples. The organic film EN2 may prevent foreign matters from being introduced to the light-emitting element OLED, and may cover a stepped portion of the components disposed under the organic film EN2. For example, the organic film EN2 may include an acrylate-based organic material. However, the material of the organic film EN2 is not limited to the above example.

The input sensing unit ISP may be disposed on the display panel DP. The input sensing unit ISP may include a base layer IL1, a first sensing insulation layer IL2, a first sensing conductive layer CL1, and a second sensing conductive layer CL2. The input sensing unit ISP may further include the second sensing insulation layer IL3 (see FIG. 5) as illustrated in FIG. 5. The above description may be equally applied to each component.

The base layer IL1 may be in contact with an uppermost layer of the encapsulation layer ECL. For example, the base layer IL1 may be in contact with the second inorganic film EN3 of the encapsulation layer ECL. The base layer IL1 of the input sensing unit ISP may be directly formed on a base surface that the encapsulation layer ECL provides. However, an embodiment of the inventive concept is not limited thereto, and the base layer IL1 may be omitted according to an embodiment. In this case, the first sensing conductive layer CL1 of the input sensing unit ISP may be in contact with the encapsulation layer ECL.

The first sensing conductive layer CL1 may be disposed on the base layer IL1, and the second sensing conductive layer CL2 may be disposed on the first sensing insulation layer IL2. The first sensing conductive layer CL1 and the second sensing conductive layer CL2 may constitute a sensing electrode TE. The sensing electrode TE may correspond to any one of the aforementioned first and second sensing electrodes TEX and TEY (see FIG. 7). For example, the first sensing conductive layer CL1 may include a connection pattern BP of the sensing electrode TE, and the second sensing conductive layer CL2 may include a sensing pattern SP of the sensing electrode TE. However, an embodiment of the inventive concept is not limited thereto, and the first sensing conductive layer CL1 may also include the sensing pattern SP, and the second sensing conductive layer CL2 may also include the connection pattern BP.

The connection pattern BP may correspond to the first connection pattern BP1 (see FIG. 7) or the second connection pattern BP2 (see FIG. 7) which are described above, and the sensing pattern SP may correspond to the first sensing pattern SP1 (see FIG. 7) or the second sensing pattern SP2 (see FIG. 7) which are described above. The connection pattern BP may be disposed on a different layer from the sensing pattern SP to be connected thereto through a contact hole that penetrates the first sensing insulation layer IL2. However, an embodiment of the inventive concept is not limited thereto, and the connection pattern BP and the sensing pattern SP may also be disposed at a same layer to be integrally formed.

The sensing electrode TE may have a mesh-shaped pattern, and may be disposed corresponding to a region where the pixel-defining film PDL is disposed. However, an embodiment of the inventive concept is not limited thereto, and the sensing electrode TE may be provided as a single shape pattern overlapping the light-emitting element OLED. In this case, the sensing electrode TE may include a transparent conductive material.

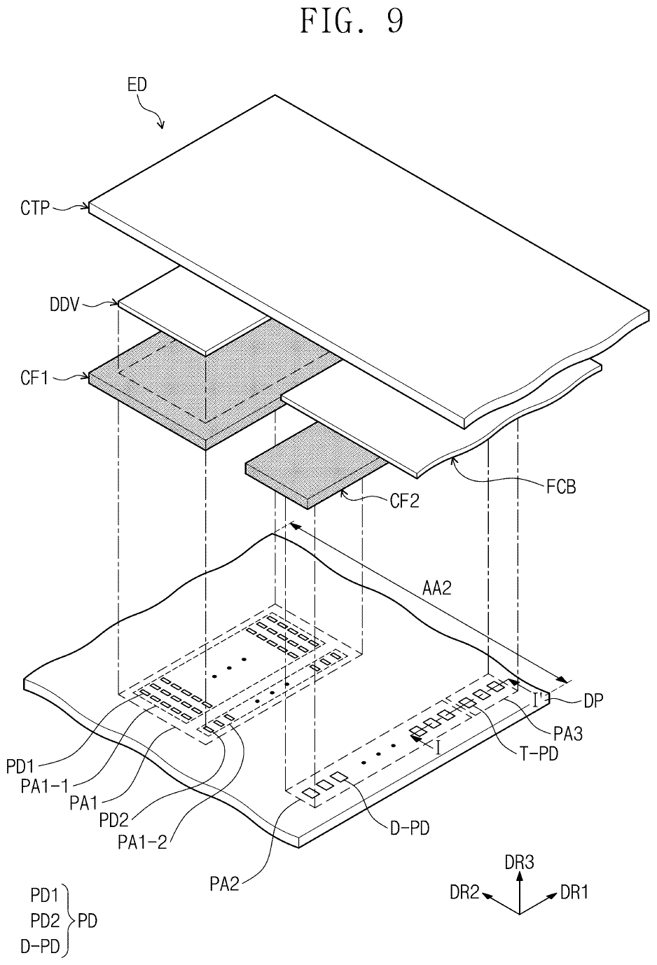

FIG. 9 is a perspective view of an electronic device according to an embodiment of the inventive concept. FIG. 9 briefly illustrates some components, of an electronic device ED, disposed corresponding to a second base region AA2.

The second base region AA2 corresponds to a partial region of the non-display region NDA (see FIG. 6). As illustrated in FIG. 9, among the non-display region NDA or the second base region AA2, a region where a data driver DDV is bonded may be defined as a first pad region PA1, and a region where a flexible circuit board FCB is bonded may be defined as a second pad region PA2. The second pad region PA2 may be referred to as a display pad region.

The data driver DDV may be bonded to the first pad region PA1 through a first adhesive layer CF1, and the flexible circuit board FCB may be bonded to the second pad region PA2 through a second adhesive layer CF2. The first adhesive layer CF1 and the second adhesive layer CF2 may each include a synthetic resin having adhesiveness. The first adhesive layer CF1 and the second adhesive layer CF2 may each be an anisotropic conductive film. For example, the first adhesive layer CF1 and the second adhesive layer CF2 may each include an adhesive resin and conductive particles dispersed in the adhesive resin.

The first adhesive layer CF1 may overlap the first pad region PA1. The first adhesive layer CF1 may overlap the data driver DDV. The second adhesive layer CF2 may overlap the second pad region PA2 and a third pad region PA3. The second adhesive layer CF2 may overlap the flexible circuit board FCB.

The display panel DP may include a plurality of pads PD. The plurality of pads PD may include first signal pads PD1, second signal pads PD2, and display pads D-PD. The first signal pads PD1, the second signal pads PD2, and the display pads D-PD may be the pads disposed in a signal transmission path.

The first signal pads PD1 may be disposed corresponding to an output pad of the data driver DDV, and may be input pads which receive a signal from the data driver DDV. The second signal pads PD2 may be disposed corresponding to an input pad of the data driver DDV, and may be output pads which output a signal to the data driver DDV. The display pads D-PD may be panel input pads which receive a signal from the flexible circuit board FCB.

The first signal pads PD1 may each be electrically connected to the pixels PX (see FIG. 6) of the display panel DP through a signal line, and may transmit and receive a signal to and from the pixels PX (see FIG. 6). The second signal pads PD2 may each be electrically connected to a corresponding display pad D-PD of the display pads D-PD through signal wiring, and the display pads D-PD and the second signal pads PD2 which are electrically connected to each other may transmit and receive a signal.

The first pad region PA1 may include a first sub pad region PA1-1 and a second sub pad region PA1-2. The first sub pad region PA1-1 may be defined as a region where the first signal pads PD1 are disposed. The second sub pad region PA1-2 may be defined as a region where the second signal pads PD2 are disposed.

The first signal pads PD1 may be arranged along a first direction DR1 and a second direction DR2 within the first sub pad region PA1-1. Among the first signal pads PD1, the first signal pads PD1 arranged along the first direction DR1 may be defined as a pad row. FIG. 9 exemplarily illustrates that five pad rows are arranged along the second direction DR2. The arrangement of the first signal pads PD1 is not limited thereto.

The second signal pads PD2 may be arranged along the first direction DR1 within the second sub pad region PA1-2. The second signal pads PD2 may be arranged as one pad row. However, the arrangement of the second signal pads PD2 is not limited thereto.

The display panel DP may further include test pads T-PD. The test pads T-PD are pads for testing an operation of the display panel DP before attaching a circuit component (for example, a data driver, flexible circuit board, etc.) for operation of the display panel DP. The test pads T-PD may be connected to an internal circuit of the display panel DP, and the display panel DP may be operated when an operation signal is applied to the test pads T-PD.

The test pads T-PD may be arranged while being spaced apart in the first direction DR1 from the second pad region PA2 where the display pads D-PD are disposed. The region where the test pads T-PD are disposed may be defined as the third pad region PA3. The third pad region PA3 may be referred to as a test pad region. However, FIG. 9 is exemplarily illustrated, and the location where the test pads T-PD are disposed is not limited thereto.

The electronic device ED according to an embodiment may further include a conductive tape CTP. The conductive tape CTP may be disposed on the data driver DDV and the flexible circuit board FCB, and may prevent noise caused by electromagnetic waves or static electricity. The conductive tape CTP may include a conductive metal material. For example, the conductive tape CTP may contain copper or aluminum. The conductive tape CTP may overlap the first pad region PA1, the second pad region PA2, and the third pad region PA3.

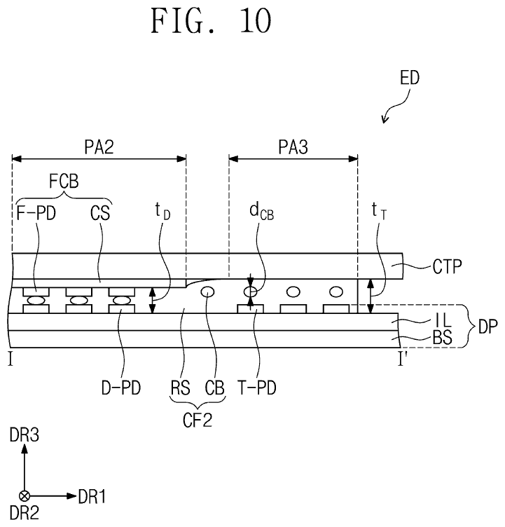

FIG. 10 is a cross-sectional view of an electronic device according to an embodiment of the inventive concept. FIG. 10 schematically illustrates a cross section taken along line I-I′ of FIG. 9. In FIG. 10 and below, for convenience of explanation, the second adhesive layer CF2 is referred to as an adhesive layer, the second pad region PA2 is referred to as a display pad region, and the third pad region PA3 is referred to as a test pad region.

At least one insulation layer IL may be disposed on a base substrate BS of a display panel DP. The insulation layer IL may be at least one of the insulation layers 10, 20, 30, 40, 50, and 60 (see FIG. 8) included in the circuit element layer CL (see FIG. 8). For example, the insulation layer IL may be an extension of the first to fourth insulation layers 10, 20, 30, and 40 (see FIG. 8) from the first base region AA1 (see FIG. 6).

Display pads D-PD may be disposed on the insulation layer IL. A region where the display pads D-PD are disposed may be defined as a display pad region PA2. The display pads D-PD may each include a conductive layer. The display pads D-PD may each include a plurality of conductive layers arranged along a thickness direction. For example, the plurality of conductive layers may include at least one among molybdenum, titanium, gold, silver, copper, aluminum, platinum, and an alloy thereof.

Test pads T-PD may be disposed on the insulation layer IL. A region where the test pads T-PD are disposed may be defined as a test pad region PA3. The test pads T-PD may each include a conductive layer.

A flexible circuit board FCB may be disposed overlapping the display pad region PA2, and not overlapping the test pad region PA3. That is, the flexible circuit board FCB may be disposed overlapping the display pads D-PD, and not overlapping the test pads T-PD. Since the flexible circuit board FCB is disposed overlapping only the display pad region PA2 and not overlapping the test pad region PA3, a thickness of an adhesive layer CF2 overlapping each of the display pad region PA2 and the test pad region PA3 may vary.

The flexible circuit board FCB may include a circuit board CS and circuit pads F-PD. On a plane, the circuit pads F-PD may be disposed corresponding to the display pads D-PD. The circuit pads F-PD may be electrically connected to the display pads D-PD through a conductive particle CB to be described later.

The adhesive layer CF2 may be disposed between the display panel DP and a conductive tape CTP. In the display pad region PA2, the adhesive layer CF2 may be disposed between the display panel DP and the flexible circuit board FCB. In the display pad region PA2, the adhesive layer CF2 may be in contact with the display pads D-PD and the circuit pads F-PD. In the test pad region PA3, the adhesive layer CF2 may be disposed between the display panel DP and the conductive tape CTP. In the test pad region PA3, the adhesive layer CF2 may be in contact with the test pads T-PD and the conductive tape CTP.

Since the flexible circuit board FCB is disposed overlapping the display pad region PA2 and not overlapping the test pad region PA3, the thickness of the adhesive layer CF2 in the display pad region PA2 and the test pad region PA3 may be different. The thickness of the adhesive layer CF2 overlapping the display pad region PA2 may be defined as a first thickness t_{D}, and the thickness of the adhesive layer CF2 overlapping the test pad region PA3 may be defined as a second thickness tr. In the display pad region PA2, a stepped portion may be formed in the adhesive layer CF2 by a thickness of the flexible circuit board FCB, and accordingly, the first thickness to may be smaller than the second thickness t_{T}.

The adhesive layer CF2 may include an adhesive resin RS and conductive particles CB dispersed within the adhesive resin RS. The adhesive layer CF2 may be an anisotropic conductive adhesive.

The adhesive resin RS may couple the flexible circuit board FCB and the display panel DP together while filling between the conductive particles CB. The adhesive resin RS may include a polymer material. For example, the adhesive resin RS may include at least one among an acrylate-based polymer, a silicon-based polymer, a urethane-based polymer and an imide-based polymer. The adhesive resin RS may be a portion formed by thermosetting or photocuring a base resin such as an acrylate-based resin, a silicon-based resin, a urethane-based resin, or an imide-based resin.

The conductive particles CB may be metal particles, alloy particles with multiple metals mixed, or the like. For example, the conductive particles CB may be metal or metal alloy particles containing at least one among silver, copper, bismuth, zinc, indium, tin, nickel, cobalt, chrome, and iron. Alternatively, the conductive particles CB may have a core portion formed from a polymer resin or the like, and a coating layer of a conductive material surrounding the core portion.

The conductive particles CB may be aligned between the display pads D-PD and the circuit pads F-PD which correspond to each other, within the adhesive resin RS. The conductive particles CB may have anisotropy such that current flows in a direction of pressure through pressurization during a process of bonding the flexible circuit board FCB. Accordingly, the display pads D-PD may be respectively electrically connected to the circuit pads F-PD through the conductive particles CB.

A distance between the display pad D-PD and the circuit pad F-PD may be equal to or smaller than a diameter of the conductive particle CB. The conductive particles CB may be compressed by the display pads D-PD and the circuit pads F-PD in a pressurization bonding process to be described later, and may be respectively in contact with the display pads D-PD and the circuit pads F-PD to be electrically connected.

In the test pad region PA3, the adhesive resin RS may cover the test pads T-PD. Since the test pads T-PD are sealed by the adhesive resin RS which is an insulating material, corrosion due to moisture penetration may be prevented.

In the test pad region PA3, the conductive particles CB may be spaced apart from the test pads T-PD with the adhesive resin RS therebetween. In addition, in the test pad region PA3, the conductive particles CB may be spaced apart from the conductive tape CTP with the adhesive resin RS therebetween. Since the conductive particles CB are arranged to be spaced apart from each of the test pads T-PD and the conductive tape CTP with the adhesive resin RS, which is the insulating material, between the conductive particles CB and the test pads T-PD, and between the conductive particles CB and the conductive tape CTP, the test pads T-PD and the conductive tape CTP may be electrically insulated. The test pads T-PD and the conductive tape CTP may be electrically insulated, thereby preventing an operational defect due to a short-circuit.

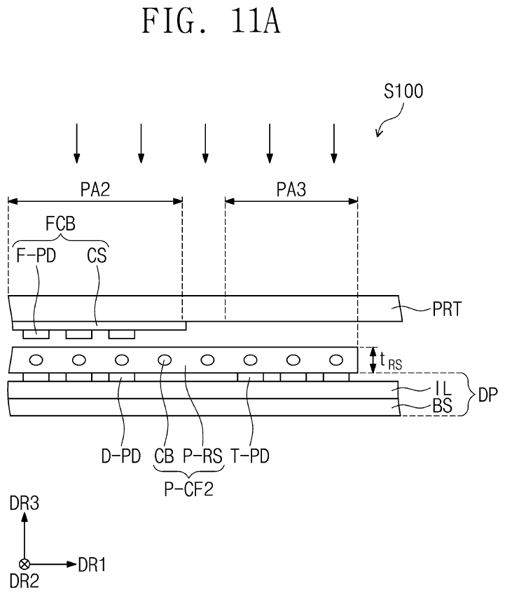

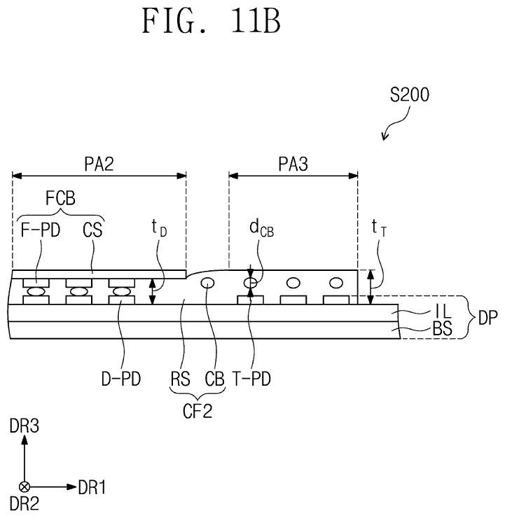

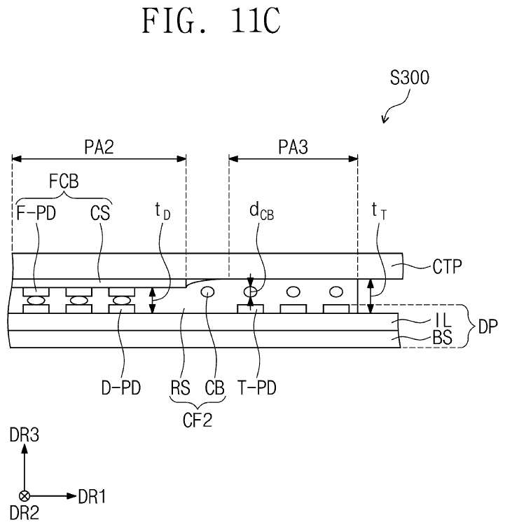

FIGS. 11A to 11C are each a schematic diagram illustrating one step of a method for manufacturing an electronic device according to an embodiment of the inventive concept. FIGS. 11A to 11C are each a schematic diagram illustrating one step of a method for manufacturing an electronic device with respect to a cross section corresponding to FIG. 10. The description made with reference to FIGS. 9 and 10 may be equally applied to FIGS. 11A to 11C, and a duplicate explanation will not be made.

A method for manufacturing an electronic device according to an embodiment includes a step S100 of compressing a flexible circuit board FCB toward a display panel DP, a step S200 of forming an adhesive layer CF2 by curing an adhesive film P-CF2, and a step S300 of disposing a conductive tape CTP.

FIG. 11A is a cross-sectional view illustrating the step S100 of compressing the flexible circuit board FCB toward the display panel DP. The display panel DP may include a display pad region PA2 where display pads D-PD are disposed and a test pad region PA3 where test pads T-PD are disposed. A step of disposing the adhesive film P-CF2 between the display panel DP and the flexible circuit board FCB may further be included before the step S100 of compressing the flexible circuit board FCB toward the display panel DP. The adhesive film P-CF2 may include an adhesive resin material P-RS and conductive particles CB disposed within the adhesive resin material P-RS. The adhesive resin material P-RS is defined as the adhesive resin material so as to distinguish the adhesive resin material from a cured adhesive resin RS to be described later.

The adhesive film P-CF2 may be disposed to overlap the display pad region PA2 and the test pad region PA3, and the flexible circuit board FCB may be disposed to overlap the display pad region PA2 and not to overlap the test pad region PA3. A thickness t_{RS} of the adhesive film P-CF2 may be constant across the display pad region PA2 and the test pad region PA3.

A compression tool PRT may be provided while overlapping the display pad region PA2 and the test pad region PA3. The flexible circuit board FCB may be provided by the compression tool PRT. The flexible circuit board FCB may be provided while being disposed on a lower surface of the compression tool PRT. Since the flexible circuit board FCB is provided overlapping the display pad region PA2 and not overlapping the test pad region PA3, a stepped portion may be made in a surface pressurizing the adhesive film P-CF2. Specifically, in the pressurization surface, a surface corresponding to the display pad region PA2 may have a structure protruding toward the adhesive film P-CF2 compared to a surface corresponding to the test pad region PA3. Accordingly, the adhesive film P-CF2 disposed in the display pad region PA2 may be formed into a more compressed shape than the adhesive film P-CF2 disposed in the test pad region PA3.

FIG. 11B is a cross-sectional view illustrating the step S200 of forming the adhesive layer CF2 by curing the adhesive film P-CF2. The adhesive film P-CF2 may be thermally cured by the compression tool PRT. The adhesive resin material P-RS may be cured to form the adhesive resin RS. FIG. 11B illustrates a cross section after the compression tool PRT is removed.

A thickness t_{D} of the adhesive layer CF2 overlapping the display pad region PA2 and a thickness t_{T} of the adhesive layer CF2 overlapping the test pad region PA3 may be formed differently, by the aforementioned step S100 of compressing to the adhesive film P-CF2. The thickness t_{D} of the adhesive layer CF2 overlapping the display pad region PA2 may be smaller than the thickness tr of the adhesive layer CF2 overlapping the test pad region PA3.

The thickness t_{D} of the adhesive layer CF2 overlapping the display pad region PA2 may be formed to a degree in which the display pads D-PD of the display panel DP and the circuit pads F-PD of the flexible circuit board FCB are respectively in contact with the conductive particles CB to be electrically connected.

The thickness t_{T} of the adhesive layer CF2 overlapping the test pad region PA3 may be greater than a diameter d_{CB} of the conductive particle CB. In addition, the conductive particles CB disposed in the adhesive layer CF2 overlapping the test pad region PA3 may be spaced apart from the test pads T-PD with the adhesive resin RS therebetween. That is, the conductive particles CB disposed in the adhesive layer CF2 overlapping the test pad region PA3 may be electrically insulated from the test pads T-PD. Therefore, an operational defect due to a short-circuit may be prevented.

In addition, the test pads T-PD may be covered by the adhesive resin RS. Specifically, the test pads T-PD may include a lower surface adjacent to a base substrate BS, an upper surface opposed to the lower surface, and a side surface connecting the upper surface and the lower surface, and the upper surface and side surface of the test pads T-PD may be covered by the adhesive resin RS. Therefore, the test pads T-PD may be sealed from the outside, and corrosion due to moisture penetration may be prevented.

FIG. 11C is a cross-sectional view illustrating the step S300 of disposing the conductive tape CTP. The conductive tape CTP may be disposed on the flexible circuit board FCB and the adhesive layer CF2. The conductive tape CTP may be disposed overlapping the display pad region PA2 and the test pad region PA3. The conductive tape CTP may be directly disposed on the flexible circuit board FCB in the display pad region PA2, and may be directly disposed on the adhesive layer CF2 in the test pad region PA3. The conductive tape CTP may serve to prevent an operational defect by preventing electromagnetic waves or static electricity.

The conductive particles CB disposed in the adhesive layer CF2 overlapping the test pad region PA3 may be arranged to be spaced apart from the conductive tape CTP with the adhesive resin RS between the conductive particles CB and the conductive tape CTP. Accordingly, the conductive particles CB disposed in the adhesive layer CF2 overlapping the test pad region PA3 may be electrically insulated from the conductive tape CTP. Therefore, an operational defect due to a short-circuit may be prevented.

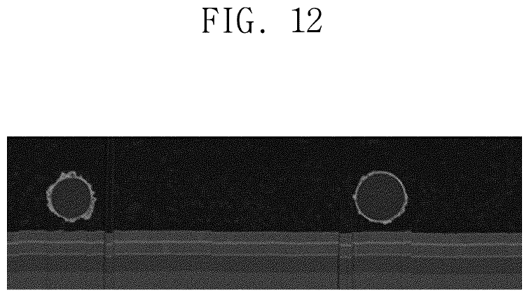

FIG. 12 is a photograph of a cross section of an electronic device according to an embodiment of the inventive concept. FIG. 12 is a photograph of a cross section of a portion of the test pad region PA3 in FIG. 10.

In FIG. 12, at a bottom, a display panel where a test pad is disposed is represented, and an adhesive layer is disposed on the display panel. The adhesive layer includes an adhesive resin and conductive particles. It is confirmed that the conductive particles are spaced apart from the test pads with the adhesive resin therebetween.

Table 1 below shows a result of reliability evaluation by manufacturing an electronic device according to the inventive concept. About 30 units of the electronic device are manufactured and evaluated. An evaluation of a short-circuit of the display panel is to evaluate whether or not there is a short-circuit defect in a test pad region where the test pads are disposed. A curing rate of the adhesive layer is to evaluate a curing degree of the adhesive resin. A high-temperature and high-humidity evaluation is to evaluate whether or not there is corrosion and a short-circuit defect after being maintained for about 500 hours at a temperature of about 85° C. and in humidity of about 85%.

TABLE 1

| | | Determi- |
|---|---|---|
| | Evaluation result of test pad region | nation |
| Short-circuit | No short-circuit defect in all 30 | PASS |
| evaluation | units | |
| of display panel | | |
| Curing rate of | About 90% or more cured in all 30 | PASS |
| adhesive layer | units | |
| High-temperature | No corrosion, short-circuit defect in | PASS |
| and high-humidity | all 30 units | |
| reliability evaluation | | |

Referring to Table 1, in an electronic device according to the inventive concept and the electronic device manufactured through a manufacturing method according to the inventive concept, it may be confirmed that the adhesive layer is sufficiently cured, and in the test pad region, the conductive particle is spaced apart from the test pad with the adhesive resin, which is an insulating material, therebetween, and thus a short-circuit defect is prevented. In addition, it may be confirmed that the test pad is sealed by being covered by the adhesive resin, and thus corrosion due to moisture penetration is prevented even in the high temperature and high humidity environment.

As mentioned above, in an electronic device according to the inventive concept, a test pad may be sealed by an adhesive layer and corrosion of the test pad due to moisture penetration may be prevented. In addition, the electronic device according to the inventive concept may include the adhesive layer having different thicknesses depending on a region, and the test pad and a conductive tape may be insulated, thereby preventing a short-circuit defect.

In addition, a method for manufacturing an electronic device according to the inventive concept may manufacture an electronic device with improved reliability by adjusting a region where an adhesive layer is disposed, without adding a separate process step.

In the above, description has been made with reference to embodiments of the inventive concept, but those skilled or of ordinary skill in the art may understand that various modifications and changes may be made to the inventive concept insofar as such modifications and changes do not depart from the spirit and technical scope of the inventive concept set forth in the claims to be described later.

Therefore, the technical scope of the inventive concept is not to be limited to the contents stated in the detailed description of the specification, but should be determined by the claims.

What is claimed is:

1. An electronic device comprising:
a display panel including a display region where a light-emitting element is disposed, and a non-display region adjacent to the display region and comprising a display pad region where a display pad is disposed and a test pad region where a test pad is disposed;
a flexible circuit board disposed on the display panel, and including a circuit pad disposed corresponding to the display pad on a plane;
a conductive tape disposed on the flexible circuit board; and
an adhesive layer disposed between the display panel and the conductive tape,
wherein on a plane, the adhesive layer overlaps the display pad region and the test pad region,
a thickness of the adhesive layer overlapping the display pad region is defined as a first thickness,
a thickness of the adhesive layer overlapping the test pad region is defined as a second thickness, and
the first thickness is smaller than the second thickness.

2. The electronic device of claim 1, wherein on a plane, the flexible circuit board overlaps the display pad region, and does not overlap the test pad region.

3. The electronic device of claim 2, wherein the flexible circuit board is disposed between the adhesive layer and the conductive tape.

4. The electronic device of claim 1, wherein the adhesive layer comprises:
an adhesive resin which includes an insulating material, and is in contact with the display panel, the flexible circuit board, and the conductive tape; and
a conductive particle disposed within the adhesive resin, and
the conductive particle is in contact with each of the display pad and the circuit pad and electrically connects the display panel and the flexible circuit board.

5. The electronic device of claim 4, wherein the adhesive resin covers the test pad.

6. The electronic device of claim 4, wherein the conductive particle included in the adhesive layer overlapping the test pad region is spaced apart from the test pad with the adhesive resin between the conductive particle and the test pad, and
the conductive particle included in the adhesive layer overlapping the test pad region is spaced apart from the conductive tape with the adhesive resin between the conductive particle and the conductive tape.

7. The electronic device of claim 1, wherein on a plane, the conductive tape overlaps the display pad region and the test pad region.

8. An electronic device comprising:
a display panel including a display region where a light-emitting element is disposed, and a non-display region adjacent to the display region and comprising a display pad region where a display pad is disposed and a test pad region where a test pad is disposed;
a flexible circuit board disposed on the display panel, and including a circuit pad disposed corresponding to the display pad on a plane;
a conductive tape disposed on the flexible circuit board; and
an adhesive layer disposed between the display panel and the conductive tape, and overlapping the display pad region and the test pad region on a plane,
wherein the adhesive layer includes an adhesive resin which contains an insulating material and is in contact with the display panel, the flexible circuit board, and the conductive tape, and a conductive particle disposed within the adhesive resin,
the conductive particle included in the adhesive layer overlapping the test pad region is spaced apart from the test pad with the adhesive resin between the conductive particle and the test pad, and
the conductive particle included in the adhesive layer overlapping the test pad region is spaced apart from the conductive tape with the adhesive resin between the conductive particle and the conductive tape.

9. The electronic device of claim 8, wherein the conductive particle is in contact with each of the display pad and the circuit pad and electrically connects the display panel and the flexible circuit board.

10. The electronic device of claim 8, wherein a thickness of the adhesive layer overlapping the display pad region is defined as a first thickness,
a thickness of the adhesive layer overlapping the test pad region is defined as a second thickness, and
the first thickness is smaller than the second thickness.

11. The electronic device of claim 8, wherein on a plane, the flexible circuit board overlaps the display pad region, and does not overlap the test pad region, and
the flexible circuit board is disposed between the adhesive layer and the conductive tape.

12. The electronic device of claim 8, wherein the adhesive resin covers the test pad.

13. The electronic device of claim 8, wherein on a plane, the conductive tape overlaps the display pad region and the test pad region.

14. The electronic device of claim 8, further comprising at least one of a processor, a memory, or a power module.

15. The electronic device of claim 8, wherein the electronic device is a television, a monitor, an outdoor billboard, a personal computer, a laptop computer, a personal digital terminal, a car's instrument cluster, a center fascia, a navigation system, a room mirror display, a game console, a smart phone, a tablet PC, a smart watch, smart glasses, a head mounted display, or a camera.

16. A method for manufacturing an electronic device, the method comprising:
disposing an adhesive film between a display panel, which includes a display pad region where a display pad is disposed and a test pad region where a test pad is disposed, and a flexible circuit board, which includes a circuit pad, and compressing the flexible circuit board toward the display panel;
forming an adhesive layer by curing the adhesive film compressed by the flexible circuit board and the display panel; and
disposing, on the flexible circuit board and the adhesive layer, a conductive tape to overlap the display pad region and the test pad region,
wherein in the compressing, the adhesive film is disposed to overlap the display pad region and the test pad region, and the flexible circuit board is disposed to overlap the display pad region and not to overlap the test pad region,
a thickness of the adhesive layer overlapping the display pad region is formed as a first thickness, and
a thickness of the adhesive layer overlapping the test pad region is formed as a second thickness which is greater than the first thickness.

17. The method of claim 16, wherein in the compressing, the flexible circuit board is disposed such that the circuit pad corresponds to the display pad.

18. The method of claim 16, wherein the adhesive layer comprises:
an adhesive resin which includes an insulating material, and is in contact with the display panel, the flexible circuit board, and the conductive tape; and
a conductive particle disposed within the adhesive resin, and
the conductive particle is in contact with each of the display pad and the circuit pad and electrically connects the display panel and the flexible circuit board.

19. The method of claim 18, wherein the conductive particle included in the adhesive layer overlapping the test pad region is spaced apart from the test pad with the adhesive resin between the conductive particle and the test pad, and
the conductive particle included in the adhesive layer overlapping the test pad region is spaced apart from the conductive tape with the adhesive resin between the conductive particle and the conductive tape.

20. The method of claim 18, wherein the adhesive resin covers the test pad.
